(19) United States
(12) Patent Application Publication
(10) Pub. No.: US 2025/0215560 A1
(43) Pub. Date: Jul. 3, 2025

(54) SYSTEMS AND METHODS FOR REMOVAL OF RESIDUE COATING DEPOSITED ON METALLIC PARTS DURING PROCESSING

(71) Applicant: ASM IP Holding B.V., Almere (NL)

(72) Inventors: Osama Khalil, Phoenix, AZ (US); Iordan Iordanov, Tempe, AZ (US); Jeffrey Hintz, Phoenix, AZ (US); David Groechel, Scottsdale, AZ (US); Lee Donohue, Avon, CT (US)

(21) Appl. No.: 18/991,902

(22) Filed: Dec. 23, 2024

Related U.S. Application Data
(60) Provisional application No. 63/615,890, filed on Dec. 29, 2023.

(51) Int. Cl. C23C 16/44

(52) U.S. Cl. CPC C23C 16/4407

(57) ABSTRACT

A method of removing atomic layer deposition (ALD) coatings from a metallic component containing titanium is provided. Systems for facilitating processes to remove inadvertent residue ALD coating on the metallic component are further disclosed. Pre-treating the metallic component containing the residue coating provide more surface area for chemical undercutting. Further, immersing the metallic component in a cleaning chemical solution and agitating the cleaning chemical solution expedites reaction between the cleaning chemical solution and the coating to remove the residue coating without etching the metallic core of the metallic component.

### CROSS REFERENCE TO RELATED APPLICATION

This application claims priority to U.S. Provisional Patent Application Ser. No. 63/615,890 filed Dec. 29, 2023, and titled SYSTEMS AND METHODS FOR REMOVAL OF RESIDUE COATING DEPOSITED ON METALLIC PARTS DURING PROCESSING, the disclosure of which is hereby incorporated by reference in its entirety.

### FIELD

The present disclosure relates to methods and apparatus for the manufacture of electronic devices. More particularly, the disclosure relates to systems and methods of removal of an atomic layer deposition coating on metallic components during processing.

### BACKGROUND

In the manufacture of integrated devices, thin layers are deposited or formed on substrates in a reaction chamber or reactor, for example, by chemical vapor deposition (CVD) or atomic layer deposition (ALD). In these deposition processes, the deposited layers are also deposited on other surfaces, for example, on components within the interior of the reaction chamber, the walls of the reaction chamber, and other exposed (e.g., wetted) surfaces within the reaction chamber. Over time, these layers, commonly referred to as “parasitic layers,” accumulate and build up, eventually flaking, shedding, and/or delaminating particles from the wetted surfaces within the reaction chamber. Particles that land on a surface of a substrate, for example, either falling on the surface or carried in a gas stream, can cause problems in the manufacturing process, for example, by reducing the yield and/or reproducibility of the process. Periodically cleaning the contaminants from the reaction chamber can reduce these problems.

One method for cleaning the components within the reaction chamber is by in-situ etching cycles using one or more cleaning cycles of suitable etchants. However, in some cases in-situ etching exhibits one or more drawbacks, for example, significantly etching the components of within the reaction chamber. Consequently, in some cases, in-situ cleaning is not feasible.

Another option for cleaning the components within the reaction chamber is ex-situ cleaning, in which the contaminated components are removed from service for cleaning. “Bead blasting” is a form of ex-situ cleaning by mechanical abrasion in which a stream of an abrasive grit, for example, alumina, zirconia, glass, silica, silicon carbide (SiC), or other suitable material, is impinged against a surface-to-be-cleaned, for example, using a high-pressure fluid stream. Bead blasting has several shortcomings, for example, damage can be caused to the reaction chamber components by the cleaning process, thereby reducing their lifetimes. Bead blasting is a “line of sight” process, resulting in difficultly in cleaning high aspect ratio components. Due to an inability to visually monitor the removal of the contaminant(s), an endpoint is not apparent, such that, when the contaminant is removed, and the underlying material is reached; there is a chance of missing a contaminated area. Bead blasting can also cause contamination of the cleaned part by the abrasive material. Contaminants that are as hard or harder than the abrasive material cannot easily be removed by bead blasting. Bead blasting also entails excessive cost and low reproducibility. Accordingly, improved components for use within a reaction chamber are desired, as well as methods for forming and utilizing the improved components.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

A method of removing atomic layer deposition (ALD) coatings from a metallic component containing titanium is provided, the method comprising: pre-treating the metallic component containing a residue coating to provide more surface area for chemical undercutting; immersing the metallic component in a cleaning chemical solution; and agitating the cleaning chemical solution to expedite reaction between the cleaning chemical solution and the residue coating.

In some embodiments, pre-treating the metallic component further comprises, performing at least one of thermal shock, laser scoring, mechanical scoring, and a high-pressure spray process.

In some embodiments, agitating the cleaning chemical solution further comprises: beginning cyclic pressurization at a first pressure value; changing a pressure of the cleaning chemical solution until the first pressure value is equal to a second pressure value; changing the pressure of the cleaning chemical solution until the second pressure value is equal to the first pressure value; oscillating between the first pressure value and the second pressure value for a determined number of cycles; and removing the metallic component from the cleaning chemical solution after completion of the determined number of cycles.

In some embodiments, the method further comprising: soaking the metallic component in the cleaning chemical solution for a given time duration after the cleaning chemical solution reaches the second pressure value; and soaking the metallic component in the cleaning chemical solution for the given time duration after the cleaning chemical solution reaches the first pressure value.

In some embodiments, the difference between the first pressure value and the second pressure value is 300 pounds per square inch (PSI).

In some embodiments, changing pressure of the cleaning chemical solution comprises changing a temperature of the cleaning chemical solution.

In some embodiments, the cyclic pressurization further comprises dissolving a gaseous component in the cleaning chemical solution to affect the pressure of the cleaning chemical solution.

In some embodiments, agitating the cleaning chemical solution further comprises at least one of sonication, sparging, and circulating the cleaning chemical solution.

In some embodiments, circulating further comprises utilizing eductor nozzles for enhancing a flow rate of the cleaning chemical solution.

In some embodiments, the method further comprises, post-treating the metallic component by performing at least one of power washing, chemical dipping, and scrubbing to remove byproducts remaining from the reaction between the cleaning chemical solution and the metallic component.

In some embodiments, the method further comprises: removing the metallic component from the cleaning chemical solution after agitation; inspecting the metallic component to determine if any residue coating remains deposited on the metallic component; and when it is determined that the residue coating remains deposited on the metallic component, immersing the metallic component in the cleaning chemical solution and performing agitation on the metallic component.

In some embodiments, agitating the cleaning chemical solution further comprises heating the cleaning chemical solution to a boiling point of the cleaning chemical solution.

In some embodiments, the cleaning chemical solution is an alkaline cleaning chemical solution.

A cleaning system is provided, the cleaning system comprising: a pre-treatment component, wherein the pre-treatment component is configured to create fault line boundaries on a metallic component, wherein the metallic component comprises a residue coating remaining from a prior deposition process. The cleaning system further comprises, a cleaning apparatus coupled to the pre-treatment component, wherein the cleaning apparatus further comprises a pressure vessel, and a cleaning chemical solution, wherein the cleaning chemical solution fills at least a portion of the pressure vessel, and wherein the cleaning chemical solution is configured to react with the residue coating on the metallic component and remove the residue coating from the metallic component. The cleaning system further comprises, an inspection component coupled to the cleaning apparatus, wherein the inspection component is configured to determine whether residue coating remains deposited on the metallic component after pre-treatment and cleaning processes.

In some embodiments, the pre-treatment component is configured to perform at least one of a thermal shock, laser scoring, mechanical scoring, and high-pressure spray process.

In some embodiments, the cleaning chemical solution comprises an alkaline cleaning chemical solution.

In some embodiments, the cleaning apparatus further comprises, a pressure control device, wherein the pressure control device is configured to fluctuate pressure within the pressure vessel between a starting pressure value and a desired pressure value for a determined number of cycles.

In some embodiments, the cleaning system further comprising, a post-treatment component, wherein the post-treatment component is configured to remove byproducts that remain on the metallic component after reaction between the cleaning chemical solution and the residue coating.

In some embodiments, the post-treatment component is configured to perform at least one of power washing, chemical dipping, and scrubbing process.

A cleaning apparatus is provided, the cleaning apparatus comprising: a pressure vessel; a cleaning chemical solution enclosed within the pressure vessel; a metallic component having a residue coating, wherein the metallic component is immersed in the cleaning chemical solution; wherein the pressure vessel is configured to oscillate pressure within the pressure vessel between a first pressure value and a second pressure value; and wherein the cleaning chemical solution is configured to etch the residue coating.

These and other embodiments will become readily apparent to those skilled in the art from the following detailed description of certain embodiments having reference to the attached figures. The disclosure is not limited to any particular embodiments disclosed.

### BRIEF DESCRIPTION OF DRAWINGS

A more complete understanding of the embodiments of the present disclosure may be derived by referring to the detailed description and claims when considered in connection with the following illustrative figures.

FIG. 1 illustrates a metallic component having a residue coating in accordance with exemplary embodiments of the disclosure.

FIG. 2 illustrates a metallic component with fault line boundaries in accordance with exemplary embodiments of the disclosure.

FIG. 3. illustrates a cleaning apparatus in accordance with example embodiments of the disclosure.

FIG. 4 illustrates a cleaned metallic core in accordance with exemplary embodiments of the disclosure.

FIG. 5 illustrates a cleaning system in accordance with exemplary embodiments of the disclosure.

FIG. 6 illustrates a method of removing a residue coating deposited on a metallic component during processing in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and structures provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As set forth in more detail below, various embodiments of the disclosure provide systems and methods to remove a parasitic layer that is inadvertently deposited on metallic components (for example, a substrate) during wafer processing. A protective layer is already deposited on the metallic component to operate as an etch-stop layer, thereby preventing the etching of the underlying metallic core of the component during the removal of the parasitic layer. In accordance with further examples of the disclosure, the protective layers of the present disclosure can operate as a sacrificial layer, such that the protective layer is selectively removed without damaging the underlying metallic core, and by the removal of the protective, the parasitic layer deposited thereon is lifted-off and removed from the metallic core of the component as well.

As used herein, the term substrate can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material or high-k dielectric material is material having a dielectric constant greater than the dielectric constant of silicon dioxide.

As used herein, the term film and/or layer can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may comprise material or a layer with pinholes and/or isolated islands. A film or layer may be at least partially continuous. A film or layer may be patterned, e.g., subdivided, and may be comprised of a plurality of semiconductor devices.

Further, in this disclosure, any two numbers of a variable can constitute a workable range of the variable, and any ranges indicated may include or exclude the endpoints. Additionally, any values of variables indicated (regardless of whether they are indicated with the term about or not) may refer to precise values or approximate values and include equivalents, and may refer to average, median, representative, majority, or the like. Further, in this disclosure, the terms including, constituted by and having refer independently to typically or broadly comprising, comprising, consisting essentially of, or consisting of in some embodiments. In this disclosure, any defined meanings do not necessarily exclude ordinary and customary meanings, in some embodiments.

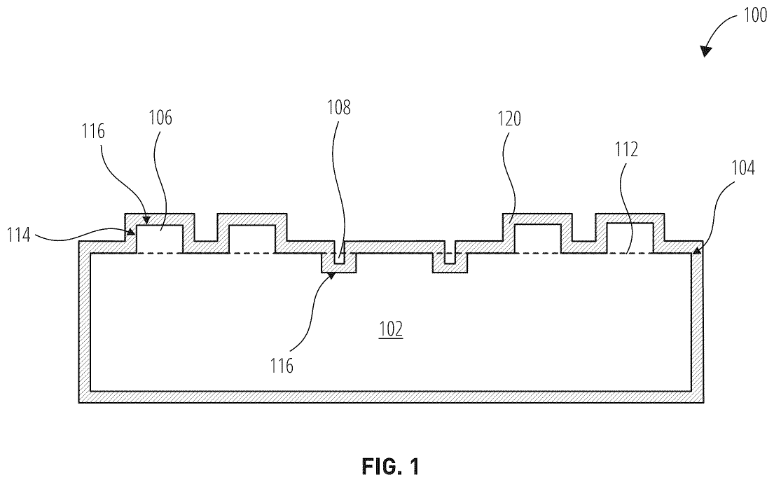

Referring now to FIG. 1, a section view of structure 100 including a metallic core 102 is shown in accordance with examples of the disclosure. The metallic core 102 includes a non-planar surface 104 including a number of features, such as raised features 106 and recessed features 108. In accordance with examples of the disclosure, the metallic core 102 can include a single element component or a multi-element component fabricated from a metallic material, or multiple metallic materials. For example, the metallic core 102 can be fabricated from a material selected from a group consisting of titanium, titanium alloys, nickel alloys (including superalloys), stainless steel, and aluminum. As a non-limiting example, the metallic core 102 can include a non-alloyed titanium material comprising a pure unalloyed titanium metal with a composition including less than 0.05 atomic percent (at-%) of nitrogen (N₂), less than 0.08 at-% of carbon (C), less than 0.015 at-% of hydrogen (H₂), less than 0.50 at-% of iron (Fe), and less than 0.40 at-% of oxygen (O₂). In further examples, the metallic core 102 can include a nickel-based superalloy, such as those commonly sold under the trademarks Haynes™, Hastelloy™, and Inconel™, for example.

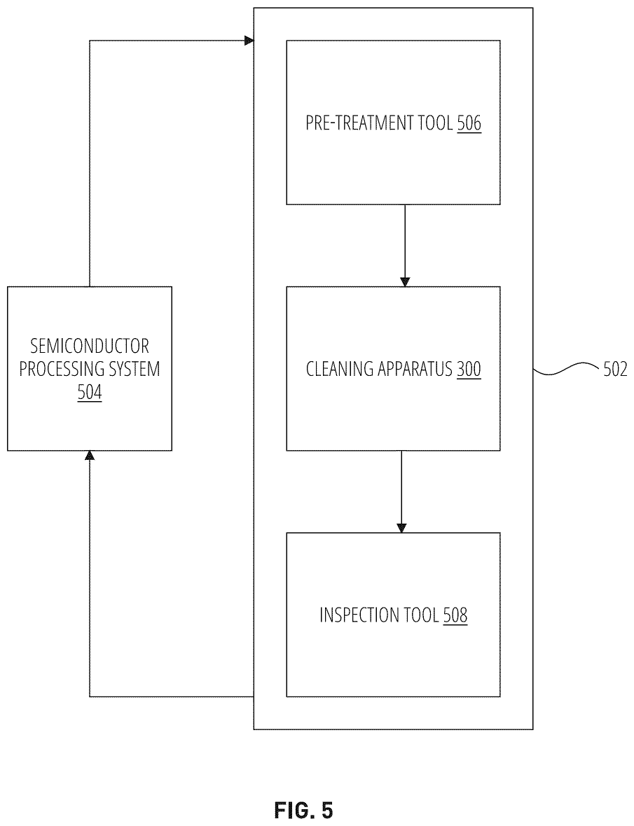

In accordance with examples of the disclosure, the metallic core 102 can comprise a number of components that can be employed within a wetted region within a reaction chamber, such as, but not limited to, a substrate support assembly, an electrostatic chuck (ESC), a process ring, a chamber wall, a base, a showerhead, a gas distribution plate, a face plate, a liner, a gas line, a shield, a remote plasma source, a flow controller, a flow equalizer, a cooling base, a chamber viewport, a chamber lid, a nozzle, and so on. In example embodiments, the structure 100 is included in a semiconductor processing system (such as semiconductor processing system 504 of FIG. 5). More specifically, in example embodiments, the structure 100 may be included in a reaction chamber of a semiconductor processing system.

As illustrated in FIG. 1, the metallic core 102 includes a non-planar surface 104. The non-planar surface 104 of the metallic core 102 can comprise at least one of nickel, copper, cobalt, chromium, molybdenum, stainless steel, ruthenium, tungsten, platinum, titanium, aluminum, or a mixture thereof. The non-planar surface 104 should not be construed as limited to this list. Other metallic surfaces that may have a naturally occurring native metal oxide or that may readily form a metal oxide upon exposure to certain oxidants (e.g., ozone, water, oxygen) may be suitably used herein as the non-planar surface 104.

In accordance with examples of the disclosure, the non-planar surface 104 can include a number of non-planar features, such as one or more raised features 106 and/or one or more recessed features 108. For example, a raised feature 106 and a recessed feature 108 can include features that are above and below the major plane 112 of the metallic core 102, respectively.

FIG. 1 illustrates an exemplary raised feature 106 and an exemplary recessed feature 108, wherein both exemplary non-planar features have vertical surfaces 114 and horizontal surfaces 116. It should be noted that the vertical surfaces 114 are not necessarily absolutely vertical (i.e., vertical surfaces 114 do not necessarily need to be at 90° to the major plane 112). Likewise, the horizontal surfaces 116 are not necessarily absolutely horizontal (i.e., horizontal surfaces 116 do not necessarily need to be at 0° (e.g., parallel) to the major plane 112.

In accordance with examples of the disclosure, the raised/recessed features (106, 108) can have a height/depth greater than 1 μm, greater than 10 μm, greater than 50 μm, greater than 100 μm, greater than 250 μm, greater than 500 μm, greater than 750 μm, greater than 1000 μm, or between 1 μm and 1000 μm. Further, in such examples, the raised/recessed features (106, 108) can have a height/depth greater than 1 mm, greater than 2 mm, greater than 3 mm, greater than 4 mm, greater than 5 mm, greater than 10 mm, greater than 20 mm, greater than 30 mm, greater than 50 mm, greater than 100 mm, or between 1 mm and 100 mm.

In accordance with examples of the disclosure, the raised features 106 and the recessed features 108 can include high aspect ratio features. Such high aspect ratio features may have an aspect ratio (height:width) which may be greater than 2:1, or greater than 5:1, or greater than 10:1, or greater than 25:1, or greater than 50:1, or even greater than 100:1, wherein “greater than” as used in this example refers to a greater distance in the height (or depth) of the feature.

In accordance with examples of the disclosure, the non-planar features (e.g., 106 and 108) can include, but are not limited to pillars, pins, columns, apertures, holes, vias, channels, etc. In exemplary embodiments, the raised features 106 can include vertical pins protruding from a surface of a metallic core comprising a substrate support assembly. In further exemplary embodiments, the recessed features 108 can include apertures indented into a surface of a metallic core comprising a gas distribution plate.

Further, as shown in FIG. 1 the surface of metallic core 102 is covered with a residue coating 120. Residue coating 120 may include a layer of metal oxide that remains on metallic core 102 after processing within the reaction chamber of a semiconductor processing system (such as the exemplary semiconductor processing system 504 illustrated and described below with reference to FIG. 5). That is, deposition of a metal oxide on a substrate may inadvertently form a parasitic layer on metallic core 102. In example embodiments, this parasitic layer may include hafnium oxide. Accordingly, residue coating 120 may include a parasitic layer of metal oxide formed on the metallic core 102.

Additionally, in example embodiments, residue coating 120 may also include a protective layer (not illustrated). Metallic components of metallic core 102 can have etching properties similar to the parasitic layer making selective removal of the parasitic layer more complex. Accordingly, the protective layer may be disposed on metallic core 102 to prevent etching of the underlying metallic core 102 during removal of parasitic layer. The protective layer has different properties than the underlying metallic core 102, so when the protective layer is removed, the parasitic layer is also removed minimizing damage to any part of the metallic core 102. Further information relating to the use and properties of the protective layer are described in U.S. Patent Application No. 63/529,861, filed on Jul. 31, 2023, entitled, “Protected Metallic Components, Reaction Chambers Including Protected Metallic Components, and Methods for Forming and Utilizing Protected Metallic Components”, the entire contents of which is incorporated by reference herein for all purposes.

In accordance with examples of the disclosure, the protective layer comprises a material selected from a group consisting of metals, metal oxides, and metal carbides. As used herein, the term “metal” and “metals” refer to both to metal elements (e.g., aluminum, zirconium, etc.) and semi-metal elements (e.g., silicon). In further examples, the protective layer may include a material not including metallic elements. In further examples, the protective layer can include polymers, such as, fluoropolymers, for example. In accordance with examples of the disclosure, the protective layer may include a metal oxide selected from a group consisting of aluminum oxides, zirconium oxides, and tantalum oxides. Thus, residue coating 120 includes parasitic coating (for example, hafnium oxide) and protective coating (such as aluminum oxide).

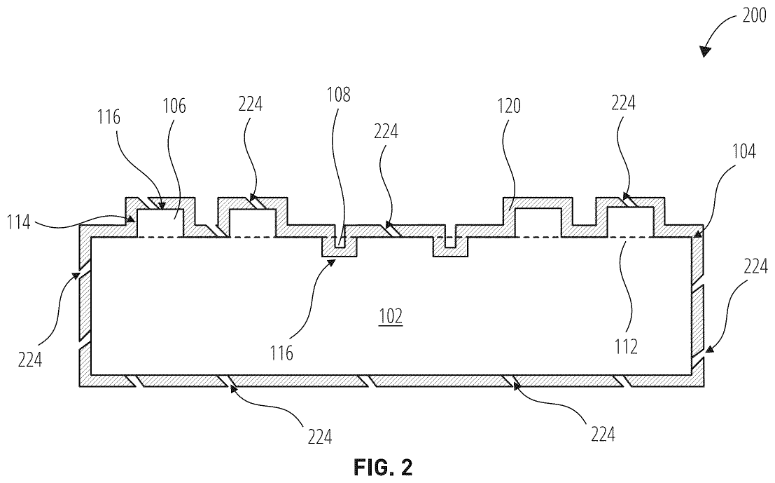

Referring now to FIG. 2, a section view of a pre-treated structure 200 is shown. Structure 200 represents structure 100 after a pre-treatment process. After removing structure 100 from the reaction chamber, a pre-treatment process is performed on structure 100. The pre-treatment process facilitates creation of new fault line boundaries 224 in residue coating 120. As shown in FIG. 2, boundaries 224 create a plurality of openings in the residue coating 120 to allow a cleaning chemical solution to interact with the protective layer for removal of residue coating 120. The pre-treatment process may include any from a group consisting of thermal shock, laser scoring, mechanical scoring, high pressure spray or other similar pre-treatment options.

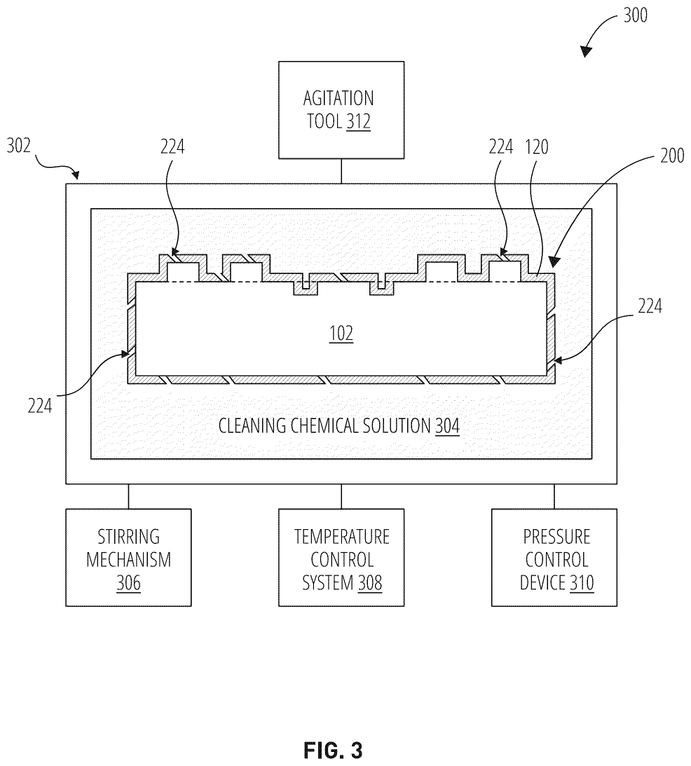

Referring now to FIG. 3, a section view of cleaning apparatus 300 is shown. Cleaning apparatus 300 includes a pressure vessel 302 containing a cleaning chemical solution 304. In example embodiments, pressure vessel 302 is an isochoric pressure vessel. Further information relating to exemplary pressure vessels are described in U.S. Patent Application Publication No. US2023/0234106, filed on Jan. 25, 2023, entitled “Coating removal system and method of operating same”, the entire contents of which is incorporated by reference herein for all purposes.

In some embodiments, the cleaning apparatus 300 further includes a means to stir the cleaning chemical solution 304. In such embodiments, cleaning apparatus 300 can comprise a stirring mechanism 306. In one aspect, the stirring mechanism 306 can include a magnetic stirrer that employs a rotating magnetic field to cause a stir bar (not illustrated) immersed in the cleaning chemical solution 304 to spin rapidly, thus stirring the cleaning chemical solution 304. In another aspect, the stirring mechanism 306 can comprise an overhead stirrer (not illustrated) which includes a motorized mechanism that drives a stirring rod or paddle immersed in the cleaning chemical solution 304. In a further aspect, the stirring mechanism 306 can comprise a vortex mixer that creates a vortex in the cleaning chemical solution 304.

In some embodiments, the cleaning apparatus 300 can include a means to control the temperature in the pressure vessel 302. In such embodiments, cleaning apparatus 300 can comprise a temperature control system 308. In one aspect, the temperature control system 308 can comprise a programmable logic controller (PLC) based system that uses PLC to manage a heater and temperature sensor (not illustrated) to enable temperature control of the cleaning chemical solution 304 (e.g., through closed loop control).

In some embodiments, the cleaning apparatus 300 can include a means to control the pressure in the pressure vessel 302. In such embodiments, cleaning apparatus 300 can comprise a pressure control device 310. In one aspect, the pressure control device 310 can include a controller in operably communication with a pressure sensor and one or more of pneumatic, electric, and electropneumatic actuators to control the pressure in the pressure vessel 302.

In accordance with examples of the disclosure, cleaning chemical solution 304 may include an aqueous alkaline cleaning chemical solution 304. In some example embodiments, cleaning chemical solution 304 includes sodium hydroxide. In example embodiments, cleaning chemical solution 304 includes potassium hydroxide. In example embodiments, cleaning chemical solution is 10 to 40 percent weighted alkaline cleaning chemical solution 304. In example embodiments, cleaning chemical solution 304 may be an acidic cleaning chemical solution.

As shown in FIG. 3, pre-treated structure 200 is immersed in the pressure vessel 302 that is filled with the cleaning chemical solution 304. In example embodiments, the volume of cleaning chemical solution 304 is half of the volume available within pressure vessel 302. In example embodiments, the amount of cleaning chemical solution 304 in the pressure vessel 302 is determined based on the volume of structure 200 such that structure 200 can be immersed in pressure vessel 302 to completely be surrounded by cleaning chemical solution 304. In example embodiments, pressure vessel 302 is completely filled with cleaning chemical solution 304.

Cleaning chemical solution 304 is designed to interact with residue coating 120. Accordingly, after structure 200 is immersed in pressure vessel 302, cleaning chemical solution 304 is configured to etch residue coating 120 without corroding metallic core 102. The cleaning chemical solution 304 is able to penetrate through top layers (for example, parasitic layer such as hafnium oxide) of residue coating 120 and reach lower layers (for example, protective layer such as aluminum oxide) via boundaries 224. As discussed herein, the lower layer is chemically attacked (e.g., etched) by cleaning chemical solution 304 and consequently, the super positioned top layer that may be fused to the lower level is also removed with minimum damage to metallic core 102.

The pressure vessel 302 is engineered as a chemical cleaning tank that can be heated, pressurized, and/or agitated to enable fast removal rates of residue coating 120, e.g., by employing one or more of the stirring mechanism 306, the temperature control system 308, and the pressure control device 310. In example embodiments, cleaning chemical solution 304 is heated to accelerate its reaction with residue coating 120. In example embodiments, cleaning chemical solution 304 is heated at or near boiling. In example embodiments, cleaning chemical solution 304 can become superheated by elevation in pressures. In example embodiments, cleaning chemical solution 304 is heated to at least 120 degrees Celsius for cleaning chemical solution 304 to react with residue coating 120.

In example embodiments in accordance with this disclosure, pressure fluctuation can expedite the reaction between cleaning chemical solution 304 and residue coating 120. After immersing pre-treated structure 200 in cleaning chemical solution 304, a starting pressure is introduced in pressure vessel 302, e.g., by employing the pressure control device 310. After the pressure inside pressure vessel 302 reaches a desired pressure, the conditions in pressure vessel 302 can be changed to fluctuate pressure back to the starting value or a different desired pressure value. Accordingly, pressure vessel 302 is configured to have the pressure oscillate between a first pressure value and a second pressure values. In example embodiments, the first pressure value is a high-pressure value, and the second pressure value is a pressure value lower than the first pressure value. Such a fluctuation between two pressure values can, thus, expedite reaction between cleaning chemical solution 304 and residue coating 120.

In example embodiments, a first pressure value is equal to the atmospheric pressure and a second pressure value is equal to approximately vacuum pressure. In example embodiments, the difference between the first pressure value and the second pressure value is 300 pounds per square inch (PSI). In exemplary embodiments, the first pressure value is 300 PSI, and the second pressure value is atmospheric pressure. In example embodiments, the difference between the first pressure value and the second pressure value is less than 300 PSI.

In examples embodiments, after immersing pre-treated structure 200 in cleaning chemical solution 304, the reaction process begins at room temperature. At room temperature, the starting pressure in pressure vessel 302 may be high. As cleaning chemical solution 304 is heated, the pressure in pressure vessel 302 decreases. When cleaning chemical solution 304 reaches its boiling point, pressure may be reintroduced by decreasing the temperature.

The cyclic pressurization of cleaning chemical solution 304 expedites reaction between cleaning chemical solution 304 and residue coating 120. The fluctuation in pressure within pressure vessel 302 enhances movement of cleaning chemical solution 304 in pressure vessel 302 and enables it to penetrate through boundaries 224 created in structure 200. The movement of cleaning chemical solution 304 may be especially beneficial in an event that structure 200 is not fully immersed in cleaning chemical solution 304. In such an example embodiment, the movement of cleaning chemical solution 304 due to cyclic pressurization prevents cleaning chemical solution 304 from settling in the bottom of pressure vessel 302. In some embodiments, the pressure control device 310 includes a pressure sensor that is coupled to pressure vessel 302 to verify its internal pressure.

In example embodiments, pressure vessel 302 may be coupled with an agitation tool 312. In example embodiments, agitation tool 312 includes a sparging semiconductor processing system. In example embodiments, cyclic pressurization can be affected by introducing various gaseous components to pressure vessel 302 and consequently, cleaning chemical solution 304. These gaseous components may include nitrogen, argon, or other similar gases. Dissolution of the gases within cleaning chemical solution 304 may result in pressure changes effecting the rate of reaction between cleaning chemical solution 304 and residue coating 120.

In example embodiments, after the pressure within pressure vessel 302 reaches a first pressure value, structure 200 is allowed to soak in cleaning chemical solution 304 for a first determined time period prior to changing the pressure back to a second pressure value. Similarly, in example embodiments, after the pressure within pressure vessel 302 reaches the second pressure value, structure 200 is allowed to soak in cleaning chemical solution 304 for a second determined time period prior to changing the pressure back to the first pressure value. In some examples, the first determined time period and the second determined time period are equal. In other examples, the first determined time period and the second determined time period are different.

In example embodiments, the cleaning apparatus 300 includes the agitation tool 312 which can comprise a sonication system. The sonication system introduces movement to cleaning chemical solution 304 by apply sound energy and enhances its reaction with residue coating 120. In example embodiments, agitation tool 312 includes additives that enhance layer penetration and etch rates. In example embodiments, agitation tool 312 includes jets that can improve reaction rate of cleaning chemical solution 304 with residue coating 120 by removing reaction products and further renewing the cleaning chemical solution 304. In example embodiments, these jets include an eductor nozzle.

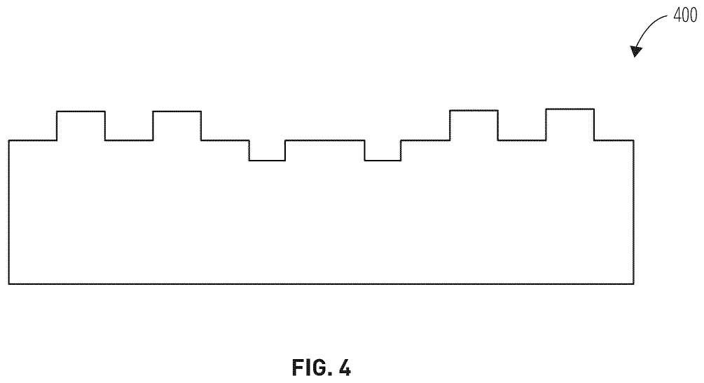

Referring now to FIG. 4, a section view of a clean structure 400 is shown. The cleaning process performed by cleaning apparatus 300 results in a substantially clean structure 400 as illustrated in FIG. 4. After completing cyclic pressurization, clean structure 400 is removed from pressure vessel 302. As shown in FIG. 4, no residue coating is visible on metallic core 102. However, in some example embodiments, byproducts may remain on clean structure 400 after it is removed from pressure vessel 302. Accordingly, in some example embodiments, clean structure 400 is then post-treated to remove any residue coating 120 that remains on metallic core 102 or to remove any reaction byproducts that may have developed during wet chemical removal process of FIG. 3. In example embodiments, post-treatment includes at least one of power washing, chemical dip, scrubbing, acid soak or any other similar process to remove reaction byproducts that remain on metallic core 102 after wet chemical removal.

After removal from the pressure vessel 302 and optional post-treatment, clean structure 400 is inspected for residue coating that may still remain deposited on metallic core 102. If residue coating remains on metallic core 102, clean structure 400 is yet again immersed in pressure vessel 302 and wet chemical removal process is performed again. When inspection indicates that clean structure 400 is clear of any residue coating (including parasitic and protective layer), clean structure 400 may be returned to the semiconductor processing system.

Referring now to FIG. 5, a block diagram illustrating the various systems, tools, and apparatus employed in the cleaning processes of the present disclosure. As shown in FIG. 5, a semiconductor processing system 504 is shown. Semiconductor processing system 504 includes structure 100 (See FIG. 1) prior to the cleaning processes. To remove residue coating 120, structure 100 is removed from semiconductor processing system 504 and processed in cleaning system 502.

Cleaning system 502 includes a pre-treatment tool 506, the cleaning apparatus 300 (as described previously) and an inspection tool 508. Structure 100 is processed using the pre-treatment tool 506. Pre-treatment tool 506 may be configured to create new fault line boundaries in residue coating of structure 100 (as illustrated in FIG. 2). In example embodiments, the pre-treatment tool 506 is configured to perform any of thermal shock, laser scoring, mechanical scoring, high pressure spray or other similar processes. Accordingly, the pre-treatment tool 506 results in a pre-treated structure 200 (as illustrated in FIG. 2).

The pre-treated structure 200 is then processed in the cleaning apparatus 300 (see FIG. 3). As discussed in FIG. 3, the cleaning apparatus 300 is configured to substantially remove the residue coating deposited on structure 200. After structure 200 is processed in cleaning apparatus 300, the clean structure 400 is inspected by utilizing an inspection tool 508. When the inspection tool 508 determines that a residue coating 120 remains deposited on clean structure 400, clean structures 400 is re-processed in cleaning apparatus 300. When inspection tool 508 determines that clean structure 400 is clean of a residue coating 120, clean structure 400 is reinstated in the semiconductor processing system 504.

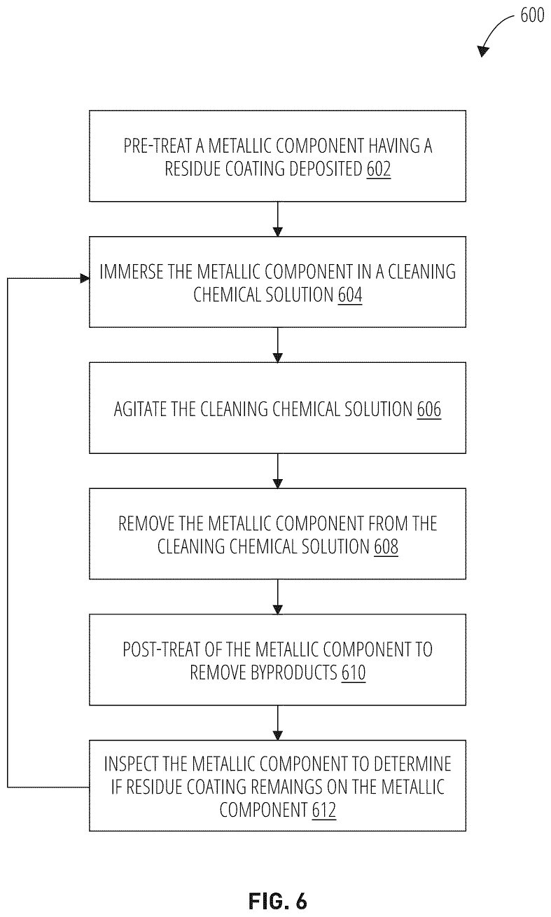

FIG. 6 illustrates a method 600 of removing atomic layer deposition (such as residue coating 120) deposited on a metallic component in accordance with examples of the disclosure. Method 600 includes pre-treating the metallic component containing a residue coating to provide more surface area for chemical undercutting (step 602). In example embodiments of method 600, pre-treating the metallic component further includes a thermal shock, laser scoring, mechanical scoring, and/or high-pressure spray process.

Method 600 further includes immersing the metallic component in a cleaning chemical solution (step 604). The cleaning chemical solution is an aqueous alkaline cleaning chemical solution. In example embodiments, the alkaline cleaning chemical solution may include sodium hydroxide. In example embodiments, the alkaline cleaning chemical solution may include potassium hydroxide. In example embodiments of method 600, 10 to 40 percent of the cleaning chemical solution is alkaline.

Method 600 also includes agitating the cleaning chemical solution to expedite reaction between the cleaning chemical solution and the residue coating (step 606). Agitation of cleaning chemical solution further comprises a process of cyclic pressurization. The cyclic pressurization process begins at a starting pressure value. The next step of the process includes changing the pressure in the pressure vessel containing the cleaning chemical solution until the starting pressure value equals a desired pressure value. In some example embodiments, the metallic component is soaked in the cleaning chemical solution for a given time duration at the desired pressure value. The next step in the process includes changing the pressure in the pressure vessel until the desire pressure value is back to the starting pressure value. In some example embodiments, the metallic component is soaked in the cleaning chemical solution for a given time duration at the staring pressure value. Accordingly, the cyclic pressurization continues the process and oscillates the pressure value between the starting pressure value (e.g., a first pressure value) and the desired pressure value (e.g., a second pressure value) for a determined number of cycles, while optionally soaking the metallic component after reaching a pressure value. After the determined number of cycles are completed, the metallic component is removed from the pressure vessel. In example embodiments, the difference between the starting pressure value and the desired pressure value is 300 PSI.

In example embodiments of method 600, changing the pressure of the cleaning chemical solution includes changing temperature of the cleaning chemical solution. In example embodiments, the cleaning chemical solution is heated to at least a temperature of 120 degrees Celsius. In example embodiments, the cleaning chemical solution is heated to a boiling point of the cleaning chemical solution.

In example embodiments of method 600, cyclic pressurization of the cleaning chemical solution includes dissolving a gaseous component in the cleaning chemical solution to affect the pressure of the cleaning chemical solution. In example embodiments, the gaseous component is at least one of argon or nitrogen.

In example embodiments of method 600, agitating the cleaning chemical solution includes introducing at least one of sonication, sparging, circulating or additives to the cleaning chemical solution to enhance movement of the cleaning chemical solution and consequently, expedite reaction of the cleaning chemical solution with the residue coating. In further example embodiments, circulating further comprises utilizing eductor nozzles for enhancing flow rate of the cleaning chemical solution.

Method 600 further includes removing the metallic component from the cleaning chemical solution after agitation (Step 608). In some example embodiments, method 600 further includes post-treating the metallic component to remove byproducts (step 610). Post-treatment may include power washing, chemical dipping, and scrubbing. Any byproducts remaining from the reaction between the cleaning chemical solution and the metallic component in step 606 can be removed through post-treatment.

Finally, method 600 comprises inspecting the metallic component to determine if any residue coating remains deposited on the metallic component (step 612). If it is determined that residue coating remains deposited on the metallic component, method 600 is repeated from step 604 by immersing the metallic component in the cleaning chemical solution and performing agitation on the metallic component. Thus, method 600 is repeated from step 604 to step 612 until the inspection determines that no residue coating remains deposited on the metallic component. After the metallic component is determined to be free of the residue coating, metallic component may be installed back in the semiconductor processing system (such as a reaction chamber of semiconductor processing system) from which it was removed.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of removing atomic layer deposition (ALD) coatings from a metallic component containing titanium, the method comprising:
pre-treating the metallic component containing a residue coating to provide more surface area for chemical undercutting;
immersing the metallic component in a cleaning chemical solution; and
agitating the cleaning chemical solution to expedite a reaction between the cleaning chemical solution and the residue coating.

2. The method of claim 1, wherein pre-treating the metallic component further comprises performing at least one of thermal shock, laser scoring, mechanical scoring, and a high-pressure spray process.

3. The method of claim 1, wherein agitating the cleaning chemical solution further comprises:
beginning cyclic pressurization at a first pressure value;
changing a pressure of the cleaning chemical solution until the first pressure value is equal to a second pressure value;
changing pressure of the cleaning chemical solution until the second pressure value is equal to the first pressure value;
oscillating between the first pressure value and the second pressure value for a determined number of cycles; and
removing the metallic component from the cleaning chemical solution after completion of the determined number of cycles.

4. The method of claim 3, further comprising:
soaking the metallic component in the cleaning chemical solution for a given time duration after the cleaning chemical solution reaches the second pressure value; and
soaking the metallic component in the cleaning chemical solution for the given time duration after the cleaning chemical solution reaches the first pressure value.

5. The method of claim 3, wherein difference between the first pressure value and the second pressure value is 300 pounds per square inch (PSI).

6. The method of claim 3, wherein changing pressure of the cleaning chemical solution comprises changing a temperature of the cleaning chemical solution.

7. The method of claim 3, wherein the cyclic pressurization further comprises dissolving a gaseous component in the cleaning chemical solution to affect the pressure of the cleaning chemical solution.

8. The method of claim 1, wherein agitating the cleaning chemical solution further comprises at least one of sonication, sparging, and circulating the cleaning chemical solution.

9. The method of claim 8, wherein circulating further comprises utilizing eductor nozzles for enhancing a flow rate of the cleaning chemical solution.

10. The method of claim 1, further comprising post-treating the metallic component by performing at least one of power washing, chemical dipping, and scrubbing to remove byproducts remaining from the reaction between the cleaning chemical solution and the metallic component.

11. The method of claim 1, further comprising:
removing the metallic component from the cleaning chemical solution after agitation;
inspecting the metallic component to determine if any residue coating remains deposited on the metallic component; and
when it is determined that the residue coating remains deposited on the metallic component, immersing the metallic component in the cleaning chemical solution and performing agitation on the metallic component.

12. The method of claim 1, wherein agitating the cleaning chemical solution further comprises heating the cleaning chemical solution to a boiling point of the cleaning chemical solution.

13. The method of claim 1, wherein the cleaning chemical solution is an alkaline cleaning chemical solution.

14. A cleaning system comprising:
a pre-treatment component, wherein the pre-treatment component is configured to create fault line boundaries on a metallic component, wherein the metallic component comprises a residue coating remaining from a prior deposition process;
a cleaning apparatus coupled to the pre-treatment component, wherein the cleaning apparatus further comprises a pressure vessel, and a cleaning chemical solution, wherein the cleaning chemical solution fills at least a portion of the pressure vessel, and wherein the cleaning chemical solution is configured to react with the residue coating of the metallic component and remove the residue coating from the metallic component; and
an inspection component coupled to the cleaning apparatus, wherein the inspection component is configured to determine whether the residue coating remains on deposited on the metallic component after pre-treatment and cleaning processes.

15. The cleaning system of claim 14, wherein the pre-treatment component is configured to perform at least one of a thermal shock, laser scoring, mechanical scoring, and high-pressure spray process.

16. The cleaning system of claim 14, wherein the cleaning chemical solution comprises an alkaline cleaning chemical solution.

17. The cleaning system of claim 14, wherein the cleaning apparatus further comprises a pressure control device, wherein the pressure control device is configured to fluctuate pressure within the pressure vessel between a starting pressure value and a desired pressure value for a determined number of cycles.

18. The cleaning system of claim 14, further comprising:
a post-treatment component, wherein the post-treatment component is configured to remove byproducts that remain on the metallic component after reaction between the cleaning chemical solution and the residue coating.

19. The cleaning system of claim 18, wherein the post-treatment component is configured to perform at least one of power washing, chemical dipping, and scrubbing process.

20. A cleaning apparatus comprising:
a pressure vessel;
a cleaning chemical solution enclosed within the pressure vessel;
a metallic component having a residue coating, wherein the metallic component is immersed in the cleaning chemical solution;
wherein the pressure vessel is configured to oscillate pressure within the pressure vessel between a first pressure value and a second pressure value; and
wherein the cleaning chemical solution is configured to etch the residue coating.
